(19) United States
(12) Patent Application Publication
(10) Pub. No.: US 2025/0373029 A1
(43) Pub. Date: Dec. 4, 2025

(54) APPARATUS AND METHOD FOR CONTROLLING A BATTERY

(71) Applicants: HYUNDAI MOTOR COMPANY, Seoul (KR); KIA CORPORATION, Seoul (KR)

(72) Inventor: Ju Seok Kim, Hwaseong-si (KR)

(73) Assignees: HYUNDAI MOTOR COMPANY, Seoul (KR); KIA CORPORATION, Seoul (KR)

(21) Appl. No.: 18/922,141

(22) Filed: Oct. 21, 2024

(30) Foreign Application Priority Data
May 30, 2024 (KR) 10-2024-0070751

(51) Int. Cl. H02J 7/00; H01M 10/42; H01M 10/48

(52) U.S. Cl. CPC H02J 7/0014; H01M 10/425; H01M 10/482; H02J 7/00302; H02J 7/00306; H02J 7/0048; H02J 7/00712; H01M 2010/4271; H02J 2207/20

(57) ABSTRACT

An apparatus for controlling a battery and a method thereof are disclosed. The apparatus includes a battery having a plurality of battery packs, a converter, a memory, and a processor. The processor distinguishes a plurality of state of charge (SOC) regions for using each of the plurality of battery packs. The processor further identifies a voltage difference between a first battery pack among the plurality of battery packs and a second battery pack among the plurality of battery packs when an SOC of each of the plurality of battery packs is included in an operation region in which each of the plurality of battery packs is usable among the plurality of SOC regions. The processor also adjusts the voltage difference between the first battery pack and the second battery pack.

### CROSS-REFERENCE TO RELATED APPLICATION

This application claims the benefit of and priority to Korean Patent Application No. 10-2024-0070751, filed in the Korean Intellectual Property Office on May 30, 2024, the entire contents of which are incorporated herein by reference.

### TECHNICAL FIELD

The present disclosure relates to an apparatus and method for controlling a battery, and more particularly, to battery pack balancing technology.

### BACKGROUND

As eco-friendly technology develops, research on the reuse of batteries mounted on eco-friendly vehicles is continuously conducted. For example, an eco-friendly vehicle may include a hybrid electric vehicle (HEV), an electric vehicle (EV), a plug-in hybrid electric vehicle (PHEV), and/or a fuel cell electric vehicle (FCEV). Reused battery packs may have different state of health (SOH) depending on their history of use in eco-friendly vehicles. Accordingly, an accident may be caused by voltage differences between reused battery packs, so there is a need to use battery packs of the same class together. However, as the classes of battery packs become more specialized, the cost of managing the battery packs may become excessive.

### SUMMARY

In view of the foregoing, there is a need to discuss research to improve the efficiency of the balancing operation to reduce the voltage difference between battery packs and to variably determine the grade of the battery packs according to the performance of the battery. The present disclosure has been made to solve the above-mentioned problems occurring in the prior art while advantages achieved by the prior art are maintained intact.

Aspects of the present disclosure provide an apparatus and a method for controlling a battery that performs a balancing operation of reducing the voltage difference between battery packs.

Other aspects of the present disclosure provide an apparatus and a method for controlling a battery that adjusts power for performing a balancing operation according to the voltage difference between battery packs.

Still other aspects of the present disclosure provide an apparatus and a method for controlling a battery that determines the grade of a battery according to a balance time for performing a balancing operation.

The technical problems to be solved by the present disclosure are not limited to the aforementioned problems. Any other technical problems not mentioned herein should be more clearly understood from the following description by those having ordinary skill in the art to which the present disclosure pertains.

According to an aspect of the present disclosure, an apparatus for controlling a battery includes the battery having a plurality of battery packs, a converter, a memory, and a processor. The processor distinguishes a plurality of state of charge (SOC) regions for using each of the plurality of battery packs. The processor further identifies a voltage difference between a first battery pack among the plurality of battery packs and a second battery pack among the plurality of battery packs when an SOC of each of the plurality of battery packs is included in an operation region in which each of the plurality of battery packs is usable among the plurality of SOC regions. The processor also adjusts the voltage difference between the first battery pack and the second battery pack based on the voltage difference and a specified voltage when a first power mode for using a balance power of the converter corresponding to the voltage difference is set.

According to an embodiment, the processor may identify whether the voltage difference is less than or equal to the specified voltage when the first power mode is set. The processor may further adjust the voltage difference between the first battery pack and the second battery pack by using the balance power of the converter corresponding to the voltage difference when the voltage difference is less than or equal to the specified voltage.

According to an embodiment, the processor may adjust the voltage difference between the first battery pack and the second battery pack by using a maximum power of the converter when the voltage difference exceeds the specified voltage.

According to an embodiment, the processor may monitor the SOC of each of the plurality of battery packs. The processor may further temporarily stop adjusting the voltage difference when at least one of an SOC of the first battery pack, an SOC of the second battery pack, or any combination thereof is out of the operation region.

According to an embodiment, the processor may adjust the balance power according to a state of health (SOH) of each of the plurality of battery packs.

According to an embodiment, the processor may distinguish the plurality of SOC regions for using each of the plurality of battery packs according to an SOH of each of the plurality of battery packs.

According to an embodiment, the plurality of SOC regions may include at least one of: a hysteresis region for preventing malfunction of the battery; an operation prohibition region for preventing at least one of overcharge of the battery, over-discharge of the battery, or any combination thereof; the operation region; or any combination thereof.

According to an embodiment, the processor may adjust the voltage difference by using a preset power of the converter when a second power mode differentiated from the first power mode is set.

According to an embodiment, the processor may identify a balance time for adjusting the voltage difference by using at least one of rated energy of the plurality of battery packs, the SOC of each of the plurality of battery packs, an SOH of each of the plurality of battery packs, or any combination thereof when the second power mode is set.

According to an embodiment, the processor may determine the preset power for adjusting the voltage difference based on identifying the balance time.

According to an embodiment, the processor may set a rating for each of the plurality of battery packs by using at least one of the balance time, the preset power, or any combination thereof.

According to an aspect of the present disclosure, a method of controlling a battery includes distinguishing a plurality of state of charge (SOC) regions for using each of a plurality of battery packs included in the battery. The method further includes identifying a voltage difference between a first battery pack among the plurality of battery packs and a second battery pack among the plurality of battery packs when an SOC of each of the plurality of battery packs is included in an operation region in which each of the plurality of battery packs is usable among the plurality of SOC regions. The method also includes adjusting the voltage difference between the first battery pack and the second battery pack based on the voltage difference and a specified voltage when a first power mode for using a balance power of a converter corresponding to the voltage difference is set.

According to an embodiment, adjusting the voltage difference may include identifying whether the voltage difference is less than or equal to the specified voltage when the first power mode is set. Adjusting the voltage difference may further include adjusting the voltage difference between the first battery pack and the second battery pack by using the balance power of the converter corresponding to the voltage difference when the voltage difference is less than or equal to the specified voltage.

According to an embodiment, adjusting the voltage difference may include adjusting the voltage difference between the first battery pack and the second battery pack by using a maximum power of the converter when the voltage difference exceeds the specified voltage.

According to an embodiment, adjusting the voltage difference may include monitoring the SOC of each of the plurality of battery packs. Adjusting the voltage difference may further include temporarily stopping adjusting the voltage difference when at least one of an SOC of the first battery pack, an SOC of the second battery pack, or any combination thereof is out of the operation region.

According to an embodiment, adjusting the voltage difference may include adjusting the balance power according to a state of health (SOH) of each of the plurality of battery packs.

According to an embodiment, distinguishing the plurality of SOC regions may include distinguishing the plurality of SOC regions for using each of the plurality of battery packs according to an SOH of each of the plurality of battery packs.

According to an embodiment, the plurality of SOC regions may include at least one of: a hysteresis region for preventing malfunction of the battery; an operation prohibition region for preventing at least one of overcharge of the battery, over-discharge of the battery, or any combination thereof; the operation region; or any combination thereof.

According to an embodiment, adjusting the voltage difference may include adjusting the voltage difference by using a preset power of the converter when a second power mode differentiated from the first power mode is set.

According to an embodiment, adjusting the voltage difference may further include identifying a balance time for adjusting the voltage difference by using at least one of rated energy of the plurality of battery packs, the SOC of each of the plurality of battery packs, an SOH of each of the plurality of battery packs, or any combination thereof when the second power mode is set.

According to an aspect of the present disclosure, an apparatus for controlling a battery includes the battery having a plurality of battery packs, a converter, a memory, and a processor. The processor distinguishes a plurality of voltage regions for using each of the plurality of battery packs. The processor further identifies a voltage difference between a first battery pack among the plurality of battery packs and a second battery pack among the plurality of battery packs when a voltage of each of the plurality of battery packs identified through the converter is included in an operation region in which each of the plurality of battery packs is usable among the plurality of voltage regions. The processor also adjusts the voltage difference between the first battery pack and the second battery pack based on the voltage difference and a specified voltage when a first power mode for using a balance power of the converter corresponding to the voltage difference is set.

According to an embodiment, the processor may monitor the voltage of each of the plurality of battery packs by using the converter. The processor may further temporarily stop adjusting the voltage difference when at least one of a voltage of the first battery pack, a voltage of the second battery pack, or any combination thereof is out of the operation region.

According to an embodiment, the processor may adjust the balance power according to a state of health (SOH) of each of the plurality of battery packs.

According to an embodiment, the processor may distinguish the plurality of voltage regions for using each of the plurality of battery packs according to an SOH of each of the plurality of battery packs.

According to an embodiment, the plurality of voltage regions may include at least one of: a hysteresis region for preventing malfunction of the battery; an operation prohibition region for preventing at least one of overcharge of the battery, over-discharge of the battery, or any combination thereof; the operation region; or any combination thereof.

### BRIEF DESCRIPTION OF THE DRAWINGS

The above and other objects, features, and advantages of the present disclosure should be more apparent from the following detailed description taken in conjunction with the accompanying drawings:

FIG. 1 is a block diagram illustrating an example of a battery control apparatus according to an embodiment of the present disclosure;

FIG. 2 is a diagram illustrating an example of a balancing operation performed by a battery control apparatus according to an embodiment of the present disclosure;

FIG. 3 is a diagram illustrating an example of an operation of performing passive balancing by a battery control apparatus according to an embodiment of the present disclosure;

FIG. 4 is a diagram illustrating an example of an operation of distinguishing a plurality of SOC regions of a battery by a battery control apparatus according to an embodiment of the present disclosure;

FIG. 5 is a table illustrating an example of power for performing active balancing by a battery control apparatus according to an embodiment of the present disclosure;

FIG. 6 is a flowchart illustrating an example of an operation of a battery control apparatus according to an embodiment of the present disclosure;

FIG. 7 is a flowchart illustrating an example of an operation of setting an operation region by a battery control apparatus according to an embodiment of the present disclosure;

FIG. 8 is a flowchart illustrating an example of an operation of a battery control apparatus according to an embodiment of the present disclosure in a power mode;

FIG. 9 is a flowchart illustrating an example of an operation of identifying a battery grade by a battery control apparatus according to an embodiment of the present disclosure;

FIG. 10 is a table illustrating an example of a battery group set according to preset power by a battery control apparatus according to an embodiment of the present disclosure;

FIG. 11 is a table illustrating examples of the grades of batteries classified by a battery control apparatus according to an embodiment of the present disclosure;

FIG. 12 is a flowchart illustrating an example of an operation of a battery control apparatus according to an embodiment of the present disclosure; and

FIG. 13 is a block diagram illustrating a computing system related to a battery control apparatus or a battery control method according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical or equivalent components are specified by the identical numerals even when they are displayed on other drawings. Further, in describing embodiments of the present disclosure, a detailed description of the related known configuration or function has been omitted where it has been determined that it would have interfered with the understanding of embodiments of the present disclosure.

In addition, terms, such as “first,” “second,” “A,” “B,” “(a),” “(b)” or the like may be used herein when describing components of the present disclosure. These terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those having ordinary skill in the art to which the present disclosure pertains. The terms defined in the generally used dictionaries should be construed as having the meanings that coincide with the meanings of the contexts of the related technologies and should not be construed as ideal or excessively formal meanings unless clearly defined in the specification of disclosure. In the present disclosure, each phrase such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

As used herein, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. According to an embodiment, the module may be implemented in a form of an application-specific integrated circuit (ASIC). According to various embodiments, operations performed by the module, the program, or another component may be carried out sequentially, in parallel, or repeatedly, or one or more of the operations may be executed in a different order or omitted, or one or more other operations may be added. When a component, controller, processor, module, unit, device, element, apparatus, or the like of the present disclosure is described as having a purpose or performing an operation, function, or the like, the component, controller, processor, module, unit, device, element, apparatus, or the like should be considered herein as being “configured to” meet that purpose or to perform that operation or function.

Various embodiments as set forth herein may be implemented as software (e.g., program) including one or more instructions that are stored in a storage medium (e.g., internal memory or external memory) that is readable by a machine (e.g., an apparatus 100 for controlling a vehicle). For example, a processor (e.g., a processor 110) of the machine (e.g., the apparatus 100 for controlling a vehicle) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. The term “non-transitory” simply means that the storage medium is a tangible device. The term not “non-transitory” does include a signal (e.g., an electromagnetic wave). However, this term does not differentiate between where data is semi-permanently stored in the storage medium and where the data is temporarily stored in the storage medium.

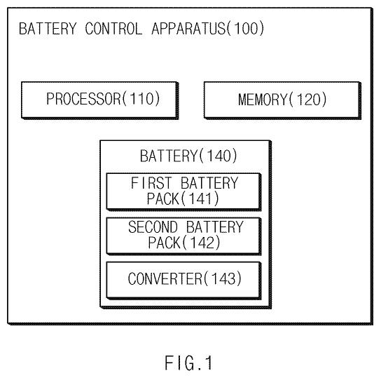

Hereinafter, embodiments of the present disclosure are described in detail with reference to FIGS. 1-13.

FIG. 1 is a block diagram illustrating an example of a battery control apparatus according to an embodiment of the present disclosure.

Referring to FIG. 1, a battery control apparatus 100 according to an embodiment of the present disclosure may be implemented inside or outside a vehicle. Some of the components included in the battery control apparatus may be implemented inside or outside the vehicle. The battery control apparatus 100 may be formed integrally with internal control devices of the vehicle or may be implemented as a separate device and connected to the control devices of the vehicle through a separate connection device. For example, the battery control apparatus 100 may further include components not shown in FIG. 1.

The battery control apparatus 100 according to an embodiment may include at least one of the processor 110, a memory 120, or a battery 140. The processor 110, the memory 120, and the battery 140 may be electrically and/or operably coupled to each other through electronic components including a communication bus. Hereinafter, hardware being operably coupled may mean that a direct connection or an indirect connection between the hardware is established wired or wirelessly, such that second hardware is controlled by first hardware among the hardware. Although shown based on different blocks, embodiments are not limited thereto. Some of the hardware in FIG. 1 (e.g., at least a portion of the processor 110, memory 120, and communication circuit (not shown)) may be included in a single integrated circuit such as a system-on-chip (SoC).

The processor 110 of the battery control apparatus 100 according to an embodiment may include a hardware component for processing data based on one or more instructions. For example, hardware components for processing include an arithmetic and logic unit (ALU), a floating point unit (FPU), a field programmable gate array (FPGA), a central processing unit (CPU), a micro controller unit (MCU), and/or an application processor (AP). The number of processors 110 may be one or more. For example, the processor 110 may have the structure of a multi-core processor including dual cores, quad cores, hexa cores, or octa cores.

The memory 120 of the battery control apparatus 100 according to an embodiment may include a hardware component for storing data and/or instructions input and/or output to the processor 110. For example, the memory 120 may include a volatile memory such as a random-access memory (RAM) and/or a non-volatile memory such as a read-only memory (ROM). For example, the volatile memory may include at least one of a dynamic RAM (DRAM), a static RAM (SRAM), a cache RAM, and a pseudo SRAM (PSRAM). For example, the non-volatile memory may include at least one of a programmable ROM (PROM), an erasable PROM (EPROM), an electrically erasable PROM (EEPROM), a flash memory, a hard disk, compact disk, and an embedded multi-media card (eMMC).

The battery 140 of the battery control apparatus 100 according to an embodiment may include a battery cell, a battery module, or a plurality of battery packs 141 and 142. For example, the battery 140 may include one or more unit cells. The battery 140 may include a capacitor or a secondary battery that stores power by charging. For example, the battery 140 may be one of a lithium ion (Li-ion) battery, a lithium ion (Li-ion) polymer battery, a lead storage battery, a nickel-cadmium (Ni—Cd) battery, a nickel metal hydride (NiMH) battery, or a lithium iron phosphate (LFP) battery. Each of the plurality of battery packs 141 and 142 may have a voltage of 400 V (volt). However, embodiments are not limited to the above.

For example, the battery 140 may include a converter 143 for adjusting the voltage difference between the plurality of battery packs 141 and 142.

In addition, the battery 140 may include a controller and/or a sensor. For example, the controller included in the battery 140 may include a battery management unit (BMU) and/or a cell monitoring unit (CMU).

For example, the sensor included in the battery 140 may transmit sensor data based on the voltage and/or current of the battery 140 to the processor 110. The processor 110, which receives the sensor data based on the voltage and/or current of the battery 140, may measure the voltage and/or current of the battery 140.

The plurality of battery packs 141 and 142 included in the battery control apparatus 100 according to an embodiment may supply power to at least one component. In an embodiment, the plurality of battery packs 141 and 142 may include a non-rechargeable primary battery, a rechargeable secondary battery, and/or a fuel cell. The plurality of battery packs 141 and 142 may be referred to as at least two battery packs, as shown in FIG. 1, in terms of including at least two battery packs.

In an embodiment, the plurality of battery packs 141 and 142 may include a plurality of relays and/or a resistor. Although the plurality of battery packs 141 and 142 are described in the present disclosure, the plurality of battery packs 141 and 142 (or battery 140) described in the present disclosure may include a battery system assembly (BSA).

For example, each of the plurality of relays included in the plurality of battery packs 141 and 142 may include a component for controlling an electric signal and/or power output from the plurality of battery packs 141 and 142. For example, the plurality of relays included in the battery pack 141 or 142 may be referred to as switches.

For example, the plurality of battery packs 141 and 142 may include at least two relays. For example, the plurality of battery packs 141 and 142 may include a first relay, a second relay, and/or a third relay. For example, the plurality of battery packs 141 and 142 may include a positive electrode relay, a negative electrode relay, and/or a pre-charge (PC) relay. However, embodiments of the present disclosure should not be limited to the above.

In an embodiment, the battery control apparatus 100 and/or each of the plurality of battery packs 141 and 142 may include a resistor (or a pre-charge resistor (PCR)). For example, the resistor may include a component for controlling the current output from each of the plurality of battery packs 141 and 142.

The battery control apparatus 100 according to an embodiment may include the plurality of battery packs 141 and 142 connected based on at least one of series, or parallel, or any combination thereof. Each of the plurality of battery packs 141 and 142 may be an example of a battery pack used for an EV. For example, each of the plurality of battery packs 141 and 142 may have different state of health (SOH) based on different usage histories. However, embodiments are not limited to the above. For example, in terms of including the plurality of battery packs 141 and 142 used for an EV, the battery control apparatus 100 may be referred to as an energy storage system (ESS).

The battery control apparatus 100 according to an embodiment may perform hybrid balancing to adjust the voltage values of the plurality of battery packs 141 and 142. The hybrid balancing may include active balancing and/or passive balancing.

For example, the active balancing may represent an operation of transferring energy from the first battery pack 141, which has relatively high energy, to the second battery pack 142, which has relatively low energy.

For example, the passive balancing may refer to an operation of dissipating energy through a resistor included in one battery pack in order to adjust the voltage of each battery cell within one battery pack.

In an embodiment, the battery control apparatus 100 may perform active balancing for adjusting the voltage difference between the plurality of battery packs 141 and 142 based on the state of charge (SOC) of the battery 140 and/or the voltage of the battery 140. The operation of adjusting the voltage difference may include an operation of transferring power energy from one battery pack to another battery pack through a converter.

If the battery control apparatus 100 according to an embodiment includes a battery system (e.g., a battery management system (BMS)), the battery control apparatus 100 may distinguish a plurality of SOC regions for using each of the plurality of battery packs 141 and 142. For example, if the battery control apparatus 100 does not include a battery system, the battery control apparatus 100 may distinguish a plurality of voltage regions for using each of the plurality of battery packs 141 and 142.

For example, the battery control apparatus 100 may distinguish the plurality of SOC regions for using each of the plurality of battery packs 141 and 142 according to the SOH of each of the plurality of battery packs 141 and 142. For example, the battery control apparatus 100 may distinguish the plurality of SOC regions according to the deterioration state of each of the plurality of battery packs 141 and 142. However, embodiments are not limited to the above.

According to an embodiment, the plurality of SOC regions may include at least one of a hysteresis region for preventing malfunction of the battery, an operation prohibition region for preventing at least one of overcharge of the battery, over-discharge of the battery, or any combination thereof, an operation region in which the plurality of battery packs 141 and 142 are usable, or any combination thereof.

If the SOC of each of the plurality of battery packs 141 and 142 is included in an operation region among the plurality of SOC regions, the battery control apparatus 100 according to an embodiment may identify the voltage difference between the first battery pack 141 among the plurality of battery packs 141 and 142 and the second battery pack 142 among the plurality of battery packs 141 and 142. For example, the battery control apparatus 100 may identify the SOC of each of the plurality of battery packs 141 and 142 through a battery system (e.g., the battery management system (BMS)).

In an embodiment, the battery control apparatus 100 may measure the voltage of each of the plurality of battery packs through the converter. For example, if the voltage of each of the plurality of battery packs 141 and 142 is included in the operation region, the battery control apparatus 100 may identify the voltage difference between the first battery pack 141 and the second battery pack 142.

If a first power mode for using a balance power (or balancing power) of the converter 143 corresponding to the voltage difference is set, the battery control apparatus 100 may adjust the voltage difference between the first battery pack 141 and the second battery pack 142 based on the voltage difference between the first battery pack 141 and the second battery pack 142 and the specified voltage.

For example, if a second power mode differentiated from the first power mode is set, the battery control apparatus 100 may adjust the voltage difference between the first battery pack 141 and the second battery pack 142 by using a preset power of the converter 143. The second power mode may represent a mode that does not use the balance power corresponding to the voltage difference.

In an embodiment, if the first power mode is set, the battery control apparatus 100 may identify whether the voltage difference between the first battery pack 141 and the second battery pack 142 is less than or equal to the specified voltage.

In an embodiment, if the voltage difference between the first battery pack 141 and the second battery pack 142 is less than or equal to the specified voltage, the battery control apparatus 100 may use the balance power of the converter 143 corresponding the voltage difference between the first battery pack 141 and the second battery pack 142, thereby adjusting the voltage difference between the first battery pack 141 and the second battery pack 142.

For example, the battery control apparatus 100 may adjust (or set) the balance power according to the state of health (SOH) of each of the plurality of battery packs.

In an embodiment, if the voltage difference between the first battery pack 141 and the second battery pack 142 exceeds the specified voltage, the battery control apparatus 100 may use the maximum power of the converter 143 to adjust the voltage difference between the first battery pack 141 and the second battery pack 142.

The battery control apparatus 100 according to an embodiment may monitor the SOC (or voltage) of each of the plurality of battery packs 141 and 142. For example, if at least one of the SOC (or voltage) of the first battery pack 141, the SOC (or voltage) of the second battery pack 142, or any combination thereof is out of the operation region, the battery control apparatus 100 may temporarily stop adjusting the voltage difference between the first battery pack 141 and the second battery pack 142.

If the second power mode is set, the battery control apparatus 100 according to an embodiment may identify the balance time for adjusting the voltage difference between the plurality of battery packs 141 and 142 by using at least one of the rated energy of the plurality of battery packs 141 and 142, the SOC of each of the plurality of battery packs 141 and 142, the SOH of each of the plurality of battery packs 141 and 142, or any combination thereof.

For example, the battery control apparatus 100 may determine a preset power for adjusting the voltage difference between the plurality of battery packs 141 and 142 based on identifying the balance time.

For example, the battery control apparatus 100 may set the grade of each of the plurality of battery packs 141 and 142 by using at least one of the balance time, the preset power, or any combination thereof.

As described above, the battery control apparatus 100 according to an embodiment may include the plurality of battery packs 141 and 142 having different usage histories. Because the plurality of battery packs 141 and 142 have different usage histories, the plurality of battery packs 141 and 142 may have different SOH. The battery control apparatus 100 may perform active balancing to reduce the SOH deviation between the plurality of battery packs 141 and 142, thereby improving the efficiency of the battery system and ensuring the safety of the battery system. In addition, the battery control apparatus 100 may perform active balancing to control the SOH deviation, thereby simplifying the balancing algorithm and reducing related facility investment costs by performing balancing without an external charger.

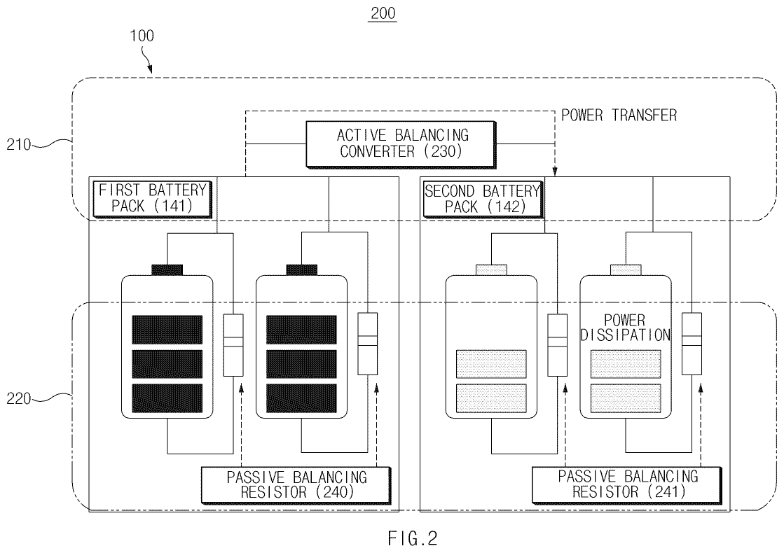

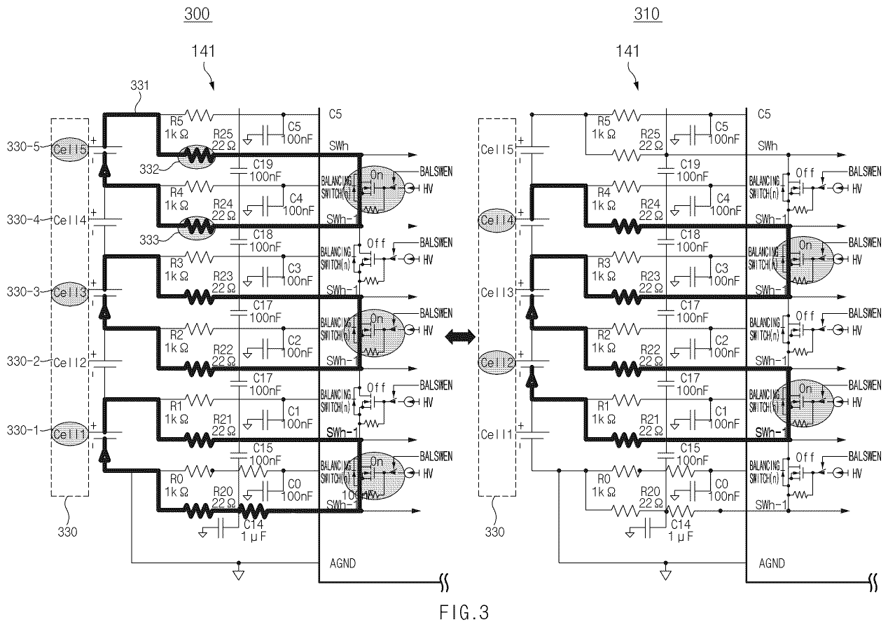

FIG. 2 is a diagram illustrating an example 200 of a balancing operation performed by a battery control apparatus according to an embodiment of the present disclosure. FIG. 3 is a diagram illustrating an example of an operation of performing passive balancing by a battery control apparatus according to an embodiment of the present disclosure. The battery control apparatus 100 of FIGS. 2 and 3 may be referenced to the battery control apparatus 100 of FIG. 1. For example, a battery (e.g., the battery 140 in FIG. 1) including the first battery pack 141 and the second battery pack 142 may be referred to as a battery rack.

For example, a battery rack, which is a type of battery system required for an energy storage device, may include individual trays in which charge/discharge batteries connected in a standing form are integrated. The battery rack may include one row of batteries as the plurality of trays located in the same horizontal direction are electrically connected in series. The battery rack may include at least one processor.

Referring to FIG. 2, the battery control apparatus 100 according to an embodiment may perform balancing to reduce the SOH deviation between the plurality of battery packs 141 and 142. The battery control apparatus 100 according to an embodiment may use a converter 230 to transfer power (or power energy) from a battery pack (e.g., the first battery pack 141) having relatively high energy to another battery pack (e.g., the second battery pack 142) having relatively low energy. The converter 230 may be referenced to the converter 143 in FIG. 1.

For example, a battery pack having relatively high energy may include a battery pack that is less deteriorated than another battery pack having relatively low energy.

The battery control apparatus 100 according to an embodiment may transfer power from the first battery pack 141 to the second battery pack 142 by performing active balancing 210.

The battery control apparatus 100 according to an embodiment may obtain voltages (or voltage values) that correspond to each of the plurality of battery packs 141 and 142. The battery control apparatus 100 may calculate a target voltage of voltage values based on obtaining voltage values corresponding to each of a plurality of battery packs. For example, at least one processor may calculate the target voltage for balancing the voltage values of the plurality of battery packs.

In an embodiment, the battery control apparatus 100 may identify at least one battery pack (e.g., the second battery pack 142) to be adjusted among the plurality of battery packs based on comparing the target voltage with each of the voltage values corresponding to each of the plurality of battery packs. For example, the battery control apparatus 100 may charge or discharge at least one battery pack by using the power of the converter 230.

In an embodiment, the battery control apparatus 100 may reduce the overall voltage difference between the batteries by performing active balancing on the first battery pack 141 and the second battery pack 142.

The battery control apparatus 100 according to an embodiment may perform passive balancing 220 for adjusting the voltage between battery cells within one battery pack. The battery control apparatus 100 may adjust the voltage difference between the battery cells included in each of the plurality of battery packs 141 and 142 by using resistors 240 and 241 included in each of the plurality of battery packs 141 and 142. For example, the battery control apparatus 100 may perform the passive balancing 220 while charging the battery.

For example, the battery control apparatus 100 may perform passive balancing by using an algorithm related to the passive balancing designed while the battery is used in an EV.

Referring to FIG. 3, one example 300 or 310 for showing the state of a plurality of battery cells 330 included in one battery pack (e.g., the first battery pack 141) among the plurality of battery packs 141 and 142 is illustrated.

For example, in the example 300, the battery control apparatus 100 may adjust the state of at least one of a plurality of relays connected to the plurality of battery cells 330. For example, the battery control apparatus 100 may adjust the state of at least one of the plurality of relays by turning on or off a balancing switch for performing passive balancing.

In an embodiment, the battery control apparatus 100 may compare the target voltage with each of the voltage values corresponding to each of the plurality of battery cells 330.

For example, the battery control apparatus 100 may identify first battery cells 330-1, 330-3, and 330-5 to consume power among the plurality of battery cells 330 based on comparing the target voltage with the voltage values corresponding to each of the plurality of battery cells 330. For example, the battery control apparatus 100 may set the states of relays related to the first battery cells 330-1, 330-3, and 330-5 to an on state. Likewise, the battery control apparatus 100 may set the states of relays related to second battery cells 330-2 and 330-4 to an off state.

In an embodiment, the battery control apparatus 100 may identify the battery pack having a voltage value included within a specified region including the target voltage, based on a comparison between the target voltage and each of the voltage values corresponding to each of the plurality of battery cells.

In an embodiment, the voltages corresponding to the first battery cells 330-1, 330-3, and 330-5 may be higher than the voltages corresponding to the second battery cells 330-2 and 330-4. For example, the battery control apparatus 100 may classify battery cells having voltage values within a specified region including the target voltage as the first battery cells 330-1, 330-3, and 330-5. For example, the battery control apparatus 100 may classify battery cells having voltage values lower than the target voltage among the plurality of battery cells 330 as the second battery cells 330-2 and 330-4. However, embodiments are not limited to the above. As an example, the battery control apparatus 100 may classify battery cells by using an identification number for each battery cell. As an example, the battery control apparatus 100 may distinguish between battery cells with identification numbers corresponding to even numbers and battery cells with identification numbers corresponding to odd numbers.

In the example 300, the battery control apparatus 100 according to an embodiment may set a closed circuit for dissipating power corresponding to the first battery cells 330-1, 330-3, and 330-5 based on setting the state of relays related to the first battery cells 330-1, 330-3, and 330-5 to the on state. The closed circuit 331 may include resistors 332 and 333.

For example, the battery control apparatus 100 may set the resistors 332 and 333 within the battery based on battery capacity.

For example, the battery control apparatus 100 may use the resistors 332 and 333 included in the closed circuit to consume power corresponding to the first battery cells 330-1, 330-3, and 330-5.

Likewise, in the example 310, the state of the relays related to the second battery cells 330-2 and 330-4 may be set to the on state and the state of the relays related to the first battery cells 330-1, 330-3, and 330-5 may be set to the off state. Based on the state of the relays related to the second battery cells 330-2 and 330-4 being set to the on state, the battery control apparatus 100 may set the closed circuit for dissipating power corresponding to the second battery cells 330-2 and 330-4. The battery control apparatus 100 may consume power corresponding to the second battery cells 330-2 and 330-4 by using the set closed circuit.

In an embodiment, the battery control apparatus 100 may reduce the voltage difference between the plurality of battery cells 330 by repeatedly performing examples 300 and 310 based on a specified number of times.

For example, if the difference in SOC between the plurality of battery cells 330 exceeds a specified value (e.g., 1%), the battery control apparatus 100 may perform balancing for the plurality of battery cells 330. For example, if the voltage difference between the plurality of battery cells 330 exceeds a specified value, balancing may be performed on the plurality of battery cells 330.

For example, the battery control apparatus 100 may perform balancing and if the voltage difference (or SOC difference) between the plurality of battery cells 330 is included in a specified region (e.g., 5 mV) for a specified time (e.g., about 10 seconds), may stop performing balancing. However, embodiments are not limited to the above.

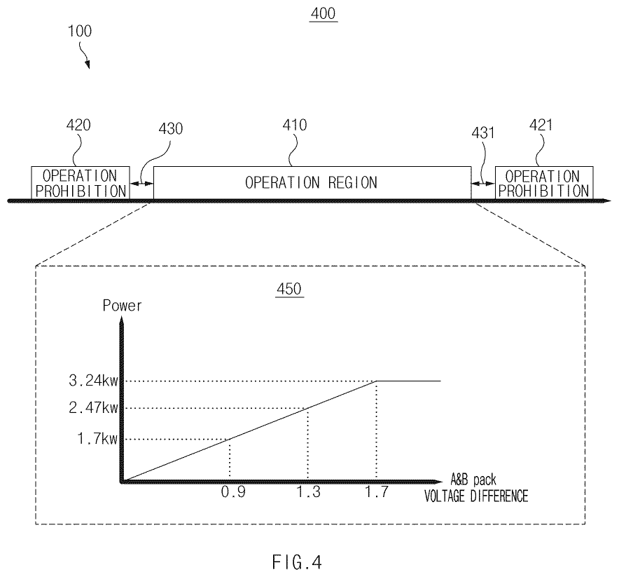

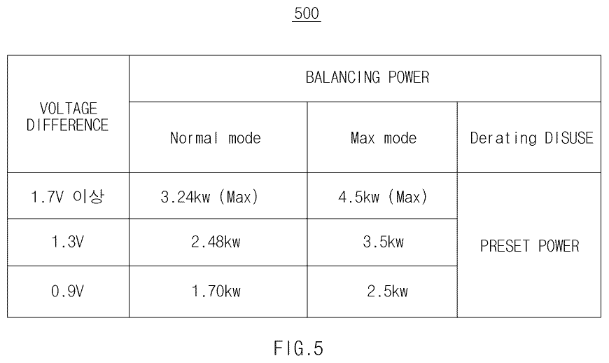

Hereinafter, with reference to FIGS. 4 and 5, the operation of adjusting the balance power of the converter while the battery control apparatus 100 performs active balancing is described in more detail.

FIG. 4 is a diagram illustrating an example of an operation of distinguishing a plurality of SOC regions of a battery by a battery control apparatus according to an embodiment of the present disclosure. FIG. 5 is a table illustrating an example of power for performing active balancing by a battery control apparatus according to an embodiment of the present disclosure. The battery control apparatus 100 of FIGS. 4 and 5 may be referenced to the battery control apparatus 100 of FIG. 1.

In an example 400, the battery control apparatus 100 may distinguish a plurality of SOC regions for using each of a plurality of battery packs (e.g., the first battery pack 141 and the second battery pack 142 of FIG. 1).

For example, the plurality of SOC areas may include at least one of hysteresis areas 430 and 431 for preventing malfunction of the battery, operation prohibition regions 420 and 421 for preventing at least one of overcharge of the battery, over-discharge of the battery, or any combination thereof, an operation region 410, or any combination thereof.

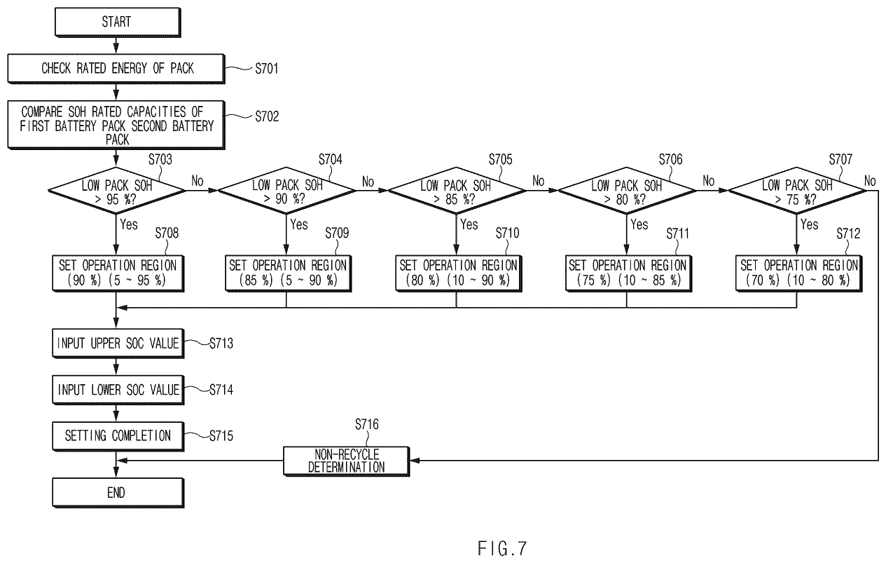

For example, the battery control apparatus 100 may set the range of the operation region according to the deterioration state (e.g., SOH) of the battery. For example, the operation of setting the range of the operation region by the battery control apparatus 100 is described in more detail below with reference to FIG. 7.

For example, the operation prohibition regions 420 and 421 may include the operation prohibition region 421 for preventing overcharging due to the voltage deviation (or SOH deviation) of the battery, and the operation prohibition region 420 for preventing over-discharge due to the voltage deviation of the battery (preventing corrosion due to potential difference or electrolyte decomposition).

According to an embodiment, if the SOC of each of the plurality of battery packs is included in the operation region 410, the battery control apparatus 100 may adjust the voltage difference between the plurality of battery packs.

Referring to FIG. 4, a graph 450 illustrates the relationship between the voltage difference between a plurality of battery packs and the balance power of a converter for performing active balancing.

The battery control apparatus 100 according to an embodiment may use the balance power to adjust the voltage difference between a plurality of battery packs while the first power mode for using the balance power corresponding to the voltage difference is set.

Referring to FIG. 5, a table 500 that illustrates the relationship between voltage difference and power according to the first power mode for using balance power corresponding to the voltage difference and the second power mode for using preset power is shown.

Referring to the table 500, the first power mode may be divided into a normal mode and a max mode. For example, the max mode may be an example of a mode for maximizing the performance (or available power) of a converter (e.g., the converter 143 in FIG. 1).

For example, an operation of performing balancing using balance power corresponding to the power difference between a plurality of battery packs may be referred to as a balancing power derating operation.

For example, the second power mode (e.g., not using derating in FIG. 5) includes a mode in which balancing is performed using a preset power (e.g., a set constant power) without using the balancing power derating operation.

Referring to the table 500, a value representing a voltage difference between a plurality of packs and a value representing balance power according to the first power mode are shown. However, embodiments are not limited thereto. For example, the battery control apparatus 100 may change the value representing the voltage difference between the plurality of packs and the value representing the balance power according to the first power mode according to battery performance characteristics.

The battery control apparatus 100 according to an embodiment may determine whether the voltage difference between a plurality of battery packs is less than or equal to a specified voltage (e.g., 1.7 V) if the first power mode is set. For example, if the voltage difference is less than or equal to a specified voltage, the battery control apparatus 100 may adjust the voltage difference by using the balance power of the converter corresponding to the voltage difference. For example, if the voltage difference exceeds the specified voltage, the battery control apparatus 100 may adjust the power difference by using the maximum power (e.g., 3.24 kw in the normal mode and 4.5 kw in the max mode) of the converter.

The battery control apparatus 100 according to an embodiment may adjust the voltage difference by using the preset power of the converter if the second power mode is set.

The battery control apparatus 100 according to an embodiment may monitor the SOC of each of the plurality of battery packs. For example, the battery control apparatus 100 may temporarily stop adjusting the voltage difference if at least one of the SOC of the first battery pack, the SOC of the second battery pack, or any combination thereof is out of the operation region.

As described above, the battery control apparatus 100 according to an embodiment may perform balancing for a plurality of battery packs more efficiently by simultaneously performing a balancing power derating control operation while performing active balancing. For example, the battery control apparatus 100 may perform balancing through power energy that is relatively large as the voltage difference becomes larger by performing the balancing power derating control operation, so that the balance time may be kept constant independent of the size of the voltage difference.

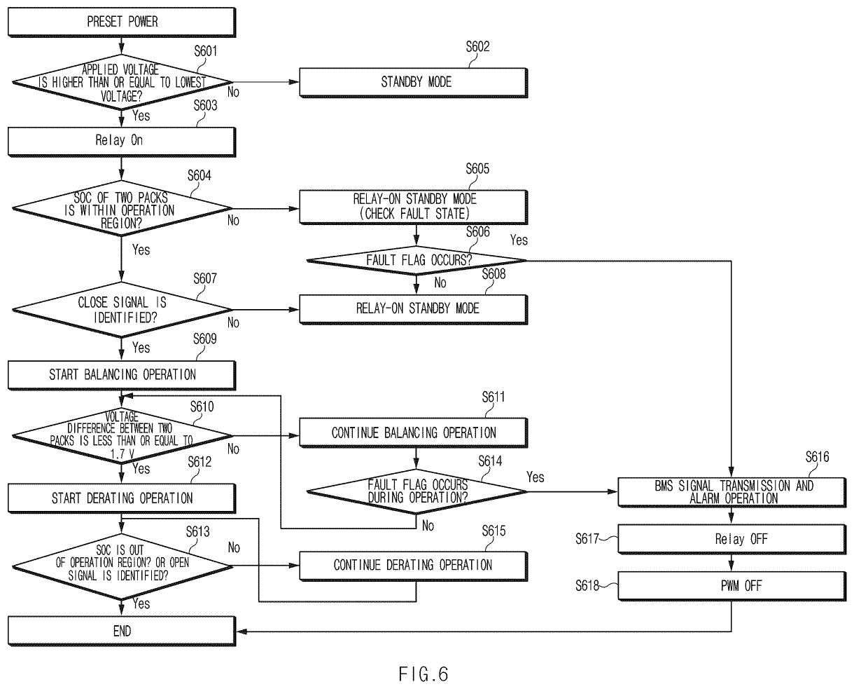

FIG. 6 is a flowchart illustrating an example of an operation of a battery control apparatus according to an embodiment of the present disclosure. Hereinafter, it is assumed that the battery control apparatus 100 of FIG. 1 performs the process of FIG. 6. In addition, it may be understood in the description of FIG. 6 that operations described as being performed by an apparatus are controlled by the processor 110 of the battery control apparatus 100. Each of the operations in FIG. 6 may be performed sequentially but is not necessarily performed sequentially. For example, the order of each operation may be changed, and at least two operations may be performed in parallel.

Referring to FIG. 6, in operation S601, the battery control apparatus according to an embodiment may determine whether the voltage of the battery is higher than or equal to the lowest voltage of the battery. For example, the lowest voltage may indicate the lowest voltage at which the battery is usable.

If the battery voltage is less than the lowest voltage (operation S601—No), in operation S602, the battery control apparatus according to an embodiment may temporarily stop using the battery. In other words, the battery control apparatus may enter a standby mode.

The battery control apparatus according to an embodiment may perform a relay-on operation in operation S603 if the voltage of the battery is higher than the lowest voltage (operation S601—Yes). The battery control apparatus may change the state of relays in the battery system to the active state (or an on state) by performing the relay-on operation.

In operation S604, the battery control apparatus according to an embodiment may determine whether the SOC of at least two battery packs (e.g., the first battery pack 141 and the second battery pack 142 in FIG. 1) is in the operation region (e.g., the operation region 410 in FIG. 4). For example, the battery control apparatus may use a battery system (e.g., BMS) to identify the SOC of a battery pack.

In an embodiment, if the battery control apparatus does not include a battery system, the battery control apparatus may determine whether to perform active balancing using the voltage measured through the converter. For example, the battery control apparatus may distinguish plurality of voltage regions for using each of the plurality of battery packs. For example, the plurality of voltage regions may include at least one of a hysteresis region for preventing malfunction of a battery, an operation prohibition region for preventing at least one of overcharge of the battery, over-discharge of the battery, or any combination thereof, the operation region, or any combination thereof. The battery control apparatus may distinguish the plurality of voltage regions for using each of the plurality of battery packs according to SOH of each of the plurality of battery packs.

For example, if a voltage of each of the plurality of battery packs identified through the converter is included in an operation region in which each of the plurality of battery packs is usable among the plurality of voltage regions, the battery control apparatus may identify the voltage difference between the first battery pack among the plurality of battery packs and the second battery pack among the plurality of battery packs. For example, if the first power mode for using the balance power of the converter corresponding to the voltage difference is set, the battery control apparatus may adjust the voltage difference between the first battery pack and the second battery pack based on the voltage difference and a specified voltage.

For example, the battery control apparatus may adjust the balance power according to the SOH of each of the plurality of battery packs.

For example, the battery control apparatus may monitor the voltage of each of the plurality of battery packs. If at least one of the voltage of the first battery pack, the voltage of the second battery pack, or any combination thereof is out of the operation region, the battery control apparatus may temporarily stop adjusting the voltage difference. If at least one of the SOCs of at least two battery packs is out of the operation range (operation S604—No), in operation S605, the battery control apparatus according to an embodiment may temporarily stop performing a relay-on operation. The battery control apparatus may check the defective condition of the battery.

In operation S606, the battery control apparatus according to an embodiment may determine whether a defect (e.g., a fault flag) occurs in the battery. For example, if a defect in the battery is not identified (operation S606—No), in operation S608, the performance of the relay-on operation may be stopped. In other words, the battery control apparatus may enter a relay-on standby mode.

For example, if a defect in the battery is identified (operation S606—Yes), in operation S616, a signal (or alarm) indicating the defect in the battery may be transmitted to a battery system (e.g., a battery management system (BMS)).

The battery control apparatus according to an embodiment may perform a relay-off operation after performing operation S616. The battery control apparatus may perform operation S616 to ensure the safety of the battery. The battery control apparatus according to an embodiment may turn off pulse width modulation (PWM) in operation S618 after performing a relay-off operation. In other words, the battery control apparatus may stop using (charging or discharging) of the battery. However, embodiments are not limited to the above.

If the SOC of at least two battery packs (e.g., the first battery pack 141 and the second battery pack 142 in FIG. 1) is within the operation region (e.g., the operation region 410 in FIG. 4) (operation S604—Yes), in operation S607, the battery control apparatus according to an embodiment may determine whether a close signal is identified. For example, the close signal may generally be used to manage battery charging and discharging. For example, the battery control apparatus may stop charging the battery by activating the close signal if the battery reaches a charging state. In addition, if the battery is discharged and reaches a safe threshold, the battery control apparatus may prevent the battery voltage from falling below the threshold by activating the close signal.

For example, if the close signal is not identified (operation S607—No), the battery control apparatus may perform operation S608.

For example, if the close signal is identified (operation S607—Yes), in operation S609, the battery control apparatus may initiate a balancing operation to adjust the voltage difference between at least two battery packs. For example, the balancing operation may be performed based on the preset power of the converter (or the maximum power of the converter).

In operation S610, the battery control apparatus according to an embodiment may determine whether the voltage difference between at least two battery packs is less than or equal to a specified voltage (e.g., 1.7 V).

For example, if the voltage difference between at least two battery packs exceeds a specified voltage (e.g., 1.7 V) (operation S610—No), in operation S611, the battery control apparatus may maintain performance of the balancing operation. For example, in operation S611, the battery control apparatus may adjust the voltage difference between at least two battery packs through the preset power of the converter.

While performing operation S611, in operation S614, the battery control apparatus according to an embodiment may monitor whether a battery defect occurs. For example, if a defect occurs in a battery (operation S614—Yes), operations S616 to S618 may be performed. For example, if any defects do not occur in the battery, operation S610 may be performed by monitoring the voltage difference between at least two battery packs.

If the voltage difference between at least two battery packs is less than or equal to a specified voltage difference (operation S610—Yes), in operation S612, the battery control apparatus according to an embodiment may initiate performing a balancing power derating operation.

In operation S613, the battery control apparatus according to an embodiment may determine whether to stop performing the balancing operation. For example, the battery control apparatus may determine whether to stop performing the balancing operation by checking whether the SOC of at least two battery packs is out of the operating region. For example, the battery control apparatus may determine whether to stop performing the balancing operation depending on whether an open signal that causes an operation opposite to that of the close signal is identified. For example, the battery control apparatus may identify the open signal obtained by the battery system.

For example, if the performing of the balancing operation is not stopped (operation S613—No), in operation S615, the battery control apparatus may maintain the performing of the balancing power derating operation. For example, the battery control apparatus may repeatedly perform operations S613 and S615.

If the performing of the balancing operation is stopped (operation S613—Yes), the battery control apparatus according to an embodiment may end performing the balancing operation.

FIG. 7 is a flowchart illustrating an example of an operation of setting an operation region by a battery control apparatus according to an embodiment of the present disclosure. Hereinafter, it is assumed that the battery control apparatus 100 of FIG. 1 performs the process of FIG. 7. In addition, it may be understood in the description of FIG. 7 that operations described as being performed by an apparatus are controlled by the processor 110 of the battery control apparatus 100. Each of the operations in FIG. 7 may be performed sequentially but is not necessarily performed sequentially. For example, the order of each operation may be changed, and at least two operations may be performed in parallel.

Referring to FIG. 7, a flowchart that illustrates an example of an operation of setting an operation region according to SOH of a battery by a battery control apparatus according to an embodiment is shown.

In operation S701, the battery control apparatus according to an embodiment may check the rated energy of a plurality of battery packs.

In operation S702, the battery control apparatus according to an embodiment may compare SOH (or rated capacity) of a first battery pack (e.g., the first battery pack 141 in FIG. 1) and SOH (or rated capacity) of a second battery pack (e.g., the second battery pack 142 in FIG. 1). The battery control apparatus may compare the SOH of the first battery pack and the SOH of the second battery pack to identify a battery pack with a relatively low SOH.

In operation S703, the battery control apparatus according to an embodiment may determine whether the SOH of a battery pack having a relatively low SOH exceeds a first value (e.g., 95%). If the SOH of the battery pack having a relatively low SOH exceeds the first value (e.g., 95%) (operation S703—Yes), in operation S708, an operation region (e.g. available SOC) according to the SOH of the battery pack may be set. For example, the battery control apparatus may set the operation region of the battery pack (e.g., usable state of charge (USOC)) to a specified value (e.g., 90%). However, embodiments are not limited to the above. For example, the battery control apparatus may set the maximum value (e.g., 95%) of the available SOC in operation S713, based on the operation region being set to a specified value (e.g., 90%). For example, the battery control apparatus may set the minimum value (e.g., 5%) of available SOC in operation S714, based on the operation region being set to a specified value (e.g., 90%).

If the SOH of the battery pack having a relatively low SOH does not exceed the first value (e.g., 95%) (operation S703—No), in operation S704, the battery control apparatus according to an embodiment may determine whether the SOH of the battery pack having a relatively low SOH exceeds a second value (e.g., 90%). If the SOH of the battery pack having a relatively low SOH exceeds the second value (e.g., 90%) (operation S704—Yes), an operation region according to the SOH of the battery pack may be set in operation S709. For example, the battery control apparatus may set the operation region of the battery pack to a specified value (e.g., 85%). However, embodiments are not limited to the above. For example, the battery control apparatus may set the maximum value (e.g., 90%) of available SOC in operation S713, based on the operation region being set to a specified value (e.g., 85%). For example, the battery control apparatus may set the minimum value (e.g., 5%) of available SOC in operation S714, based on the operation region being set to a specified value (e.g., 85%).

If the SOH of the battery pack having a relatively low SOH does not exceed the second value (e.g., 90%) (operation S704—No), in operation S705, the battery control apparatus according to an embodiment may determine whether the SOH of the battery pack with a relatively low SOH exceeds a third value (e.g., 85%). If the SOH of the battery pack with a relatively low SOH exceeds the third value (e.g., 85%) (operation S705—Yes), an operation region according to the SOH of the battery pack may be set in operation S710. For example, the battery control apparatus may set the operation region of the battery pack to a specified value (e.g., 80%). However, embodiments are not limited to the above. For example, the battery control apparatus may set the maximum value (e.g., 90%) of the available SOC in operation S713, based on the operation region being set to a specified value (e.g., 80%). For example, the battery control apparatus may set the minimum value (e.g., 10%) of available SOC in operation S714, based on the operation region being set to a specified value (e.g., 85%).

If the SOH of the battery pack having a relatively low SOH does not exceed the third value (e.g., 85%) (operation S705—No), in operation S706, the battery control apparatus according to an embodiment may determine whether the SOH of the battery pack having a relatively low SOH exceeds a fourth value (e.g., 80%). If the SOH of the battery pack having a relatively low SOH exceeds the fourth value (e.g., 80%) (operation S706—Yes), an operation region according to the SOH of the battery pack may be set in operation S711. For example, the battery control apparatus may set the operation region of the battery pack to a specified value (e.g., 75%). However, embodiments are not limited to the above. For example, the battery control apparatus may set the maximum value (e.g., 85%) of the available SOC in operation S713, based on the operation region being set to a specified value (e.g., 75%). For example, the battery control apparatus may set the minimum value (e.g., 10%) of available SOC in operation S714, based on the operation region being set to a specified value (e.g., 75%).

If the SOH of the battery pack having a relatively low SOH does not exceed the fourth value (e.g., 80%) (operation S706—No), in operation S707, the battery control apparatus according to an embodiment may determine whether the SOH of the battery pack having a relatively low SOH exceeds a fifth value (e.g., 75%). If the SOH of the battery pack having a relatively low SOH exceeds the fifth value (e.g., 75%) (operation S707—Yes), an operation region according to the SOH of the battery pack may be set in operation S712. For example, the battery control apparatus may set the operation region of the battery pack to a specified value (e.g., 70%). However, embodiments are not limited to the above. For example, the battery control apparatus may set the maximum value (e.g., 80%) of the available SOC in operation S713, based on the operation region being set to a specified value (e.g., 70%). For example, the battery control apparatus may set the minimum value (e.g., 10%) of the available SOC in operation S714, based on the operation region being set to a specified value (e.g., 70%).

If the SOH of the battery pack having a relatively low SOH does not exceed the fifth value (e.g., 75%) (operation S707—No), in operation S716, the battery control apparatus according to an embodiment may determine that it is impossible to use the battery pack. However, embodiments are not limited to the above. For example, the battery control apparatus may perform operation S716 by comparing the SOH of the battery pack with data other than the first to fifth values. For example, other data may include data having a value lower than the fifth value (e.g., 70%).

The battery control apparatus to according an embodiment may complete the setting of a plurality of SOC regions in operation S715 based on setting the operation region by performing operations S713 and S714. For example, the battery control apparatus may change the operation prohibition region (e.g., the operation prohibition region 420 or 421 in FIG. 4) and the hysteresis region (e.g., the hysteresis area 430 or 431 in FIG. 4) based on the operation region.

As described above, the battery control apparatus according to an embodiment may provide a service that allows safer use of the battery pack by setting the range of the operation region. The battery control apparatus may reduce the voltage difference between the plurality of battery packs by performing active balancing if the SOC of each of the plurality of battery packs is included in the operation region. The battery control apparatus may increase the usable time of a battery by reducing the voltage difference between the plurality of battery packs.

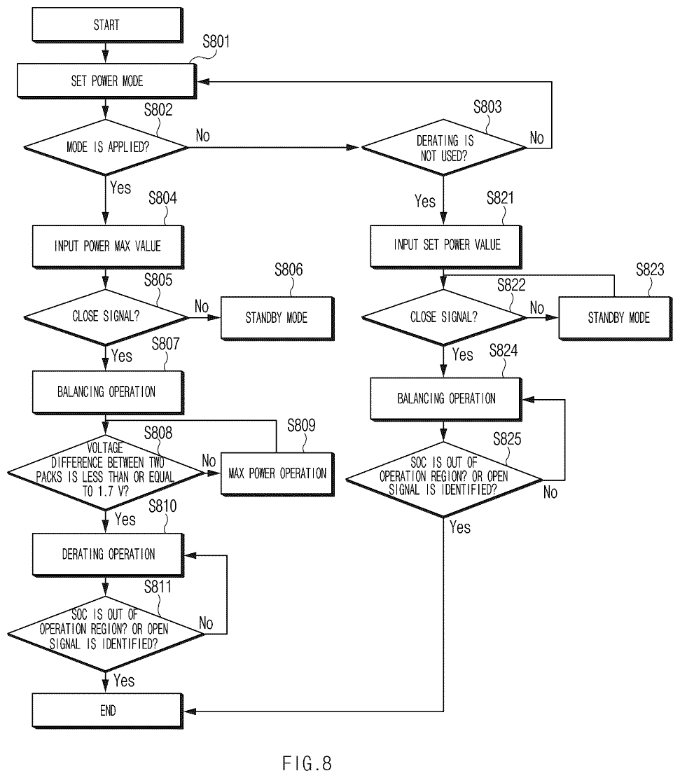

FIG. 8 is a flowchart illustrating an example of an operation of a battery control apparatus according to an embodiment of the present disclosure in a power mode. Hereinafter, it is assumed that the battery control apparatus 100 of FIG. 1 performs the process of FIG. 8. In addition, it may be understood in the description of FIG. 8 that operations described as being performed by an apparatus are controlled by the processor 110 of the battery control apparatus 100. Each of the operations in FIG. 8 may be performed sequentially but is not necessarily performed sequentially. For example, the order of each operation may be changed, and at least two operations may be performed in parallel.

Referring to FIG. 8, the battery control apparatus according to an embodiment may set the power mode in operation S801. The set power mode may include a first power mode for using the balance power of the converter corresponding to the voltage difference and a second power mode that is different from the first power mode. The first power mode may be divided into a max mode that uses the maximum allowable power of the converter and a normal mode that is differentiated from the max mode. The battery control apparatus may perform a balancing operation by using different power depending on at least one selected from among the max mode and the normal mode.

Referring to FIG. 8, in operation S802, the battery control apparatus according to an embodiment may determine whether to apply the first power mode.

For example, if the first power mode is used (operation S802—Yes), in operation S804, the maximum value of the power of the converter for performing the balancing operation may be identified. The battery control apparatus may use information such as the table 500 of FIG. 5 to identify the maximum value of the power of the converter. However, embodiments are not limited thereto.

In operation S805, the battery control apparatus according to an embodiment may check whether a close signal is identified. If the close signal is not identified (operation S805—No), in operation S806, a standby mode may be entered to temporarily stop performing g operation. For example, the battery control apparatus may check whether the close signal generated by the battery system (e.g., the battery management system (BMS)) is identified.

If the close signal is identified (operation S805—Yes), in operation S807, the battery control apparatus according to an embodiment may initiate performing a balancing operation.

In operation S808, the battery control apparatus according to an embodiment may determine whether the voltage difference between at least two battery packs is less than or equal to a specified voltage.

If the voltage difference exceeds the specified voltage (operation S808—No), in operation S809, the battery control apparatus according to an embodiment may perform a balancing operation by using the maximum value of power.

If the voltage difference is less than or equal to the specified voltage (operation S808—Yes), in operation S810, the battery control apparatus according to an embodiment may perform a balancing power derating operation. As shown in the graph 450 of FIG. 4, the battery control apparatus may dynamically perform active balancing by adjusting the power of the converter based on the power difference that changes in real time.

In operation S811, the battery control apparatus according to an embodiment may determine whether to stop the balancing operation. Operation S811 may be referenced to operation S813 of FIG. 6.

If the first power mode is not used (operation S802—No), in operation S803, it is possible to determine whether to use the second power mode. If the first power mode and the second power mode are not used (operation S803—No), the battery control apparatus may repeatedly perform operation S801.

If the second power mode is used (operation S803—Yes), in operation S821, the battery control apparatus according to an embodiment may identify a preset power for performing a balancing operation. For example, operation S822 may be referenced to operation S805. Also, operation S823 may be referenced to operation S806. In addition, operation S825 may be referenced to operation S811. Hereinafter, overlapping descriptions have been omitted.

In operation S824, the battery control apparatus according to an embodiment may reduce the voltage difference between the plurality of battery packs by using the preset power.

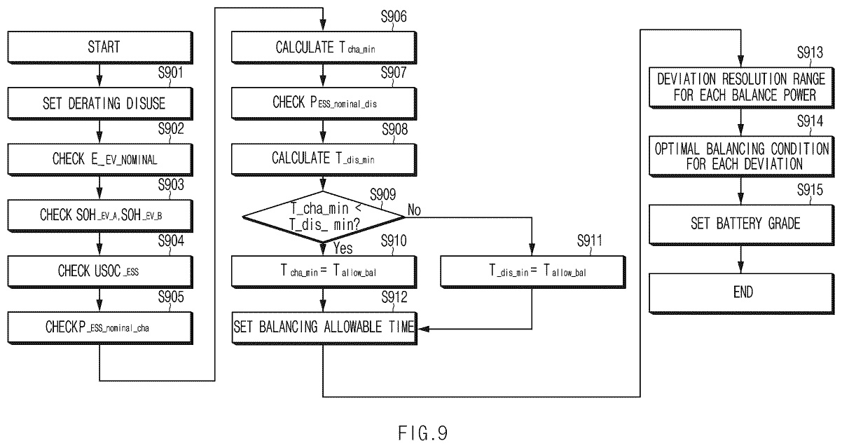

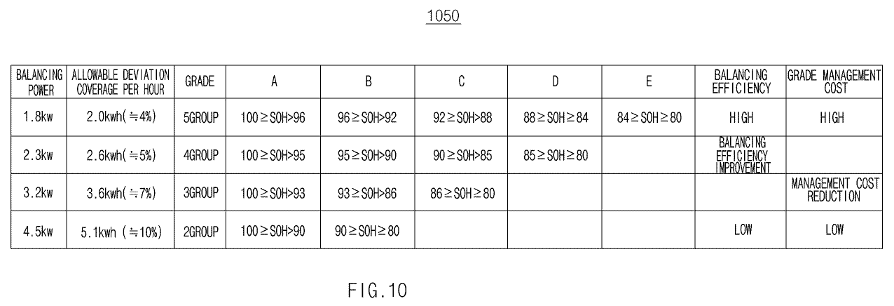

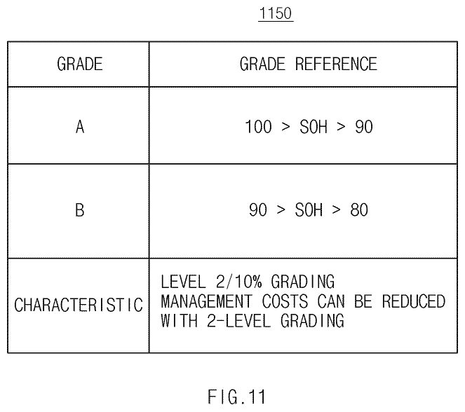

FIG. 9 is a flowchart illustrating an example of an operation of identifying a battery grade by a battery control apparatus according to an embodiment of the present disclosure. FIG. 10 is a table illustrating an example of a battery group set according to preset power by a battery control apparatus according to an embodiment of the present disclosure. FIG. 11 is a table illustrating examples of the grades of batteries classified by a battery control apparatus according to an embodiment of the present disclosure.

Hereinafter, it is assumed that the battery control apparatus 100 of FIG. 1 performs the process of FIG. 9. In addition, it may be understood in the description of FIG. 9 that operations described as being performed by an apparatus are controlled by the processor 110 of the battery control apparatus 100. Each of the operations in FIG. 9 may be performed sequentially but is not necessarily performed sequentially. For example, the order of each operation may be changed, and at least two operations may be performed in parallel.

Referring to FIG. 9, in operation S901, the battery control apparatus according to an embodiment may be set not to perform the balancing power derating operation if performing active balancing. For example, operation S901 may be performed in parallel with operation S803 of FIG. 8.

The battery control apparatus according to an embodiment may obtain a balance time for which the balancing operation is performed. For example, the balance time may be obtained by using the rated energy of a plurality of battery packs (e.g., the first battery pack 141 and the second battery pack 142 in FIG. 1), SOH of the plurality of battery packs, USOC of the battery (or ESS), the available energy of the battery (or ESS), and the rated charge/discharge power of the battery. For example, the battery control apparatus may obtain the balance time by using Equation 1 and/or Equation 2.

$${T}_{{cha}_{min}} = {[ \{ ( E ]}_{nominal} * {SOH}_{{EV}_{A}} ) + ( {E}_{nominal} * {SOH}_{{EV}_{B}} ) \} * \frac{{USOH}_{ESS}}{{P}_{{ESS}_{{nominal}_{cha}}}} \qquad [ Equation 1 ]$$

$${T}_{{dis}_{min}} = {[ \{ ( E ]}_{nominal} * {SOH}_{{EV}_{A}} ) + ( {E}_{nominal} * {SOH}_{{EV}_{B}} ) \} * \frac{{USOH}_{ESS}}{{P}_{{ESS}_{{nominal}_{dis}}}} \qquad [ Equation 2 ]$$

Referring to Equation 1 and Equation 2, Eₙₒₘᵢₙₐₗ may represent the rated energy of the battery pack. SOH_{EV}_{_{A}} may represent the SOH of the first battery pack (e.g., the first battery pack 141 in FIG. 1). SOH_{EV}_{_{B}} may represent the SOH of the second battery pack (e.g., the second battery pack 142 in FIG. 1). USOH_{ESS} may represent the available SOC of the battery.

$${P}_{E S {S}_{{nominal}_{cha}}}$$

may represent the rated charging power of the battery.

$${P}_{E S {S}_{{nominal}_{dis}}}$$

may represent the rated discharge power of the battery.

$${T}_{{cha}_{min}}$$

may represent the minimum time to fully charge the battery.

$${T}_{{dis}_{min}}$$

y represent the minimum time to completely discharge the battery. For example, the battery control apparatus may set the balance time by using the smaller value of

$${T}_{{cha}_{min}} and {T}_{{dis}_{min}} .$$

Referring to FIG. 9, in operation S902, the battery control apparatus according to an embodiment may identify the rated energy of a plurality of battery packs.

Referring to FIG. 9, in operation S903, the battery control apparatus according to an embodiment may identify the SOH of each of the plurality of battery packs.

Referring to FIG. 9, in operation S904, the battery control apparatus according to an embodiment may identify the USOC of the battery (or each of the plurality of battery packs).

Referring to FIG. 9, in operation S905, the battery control apparatus according to an embodiment may identify the rated charging power of the battery.

Referring to FIG. 9, in operation S906, the battery control apparatus according to an embodiment may identify the minimum time for fully charging the battery by using the rated energy of the plurality of battery packs, the SOH of each of the plurality of battery packs, the USOC of the battery, and/or the rated charging power of the battery obtained by performing operations S902 to S905.

Referring to FIG. 9, in operation S907, the battery control apparatus according to an embodiment may identify the rated discharge power of the battery.

Referring to FIG. 9, in operation S908, the battery control apparatus according to an embodiment may identify the minimum time for fully discharging a battery by using the rated energy of the plurality of battery packs, the SOH of each of the plurality of battery packs, the battery USOC, and/or the rated charging power of a battery obtained by performing operations S902 to S905.

Referring to FIG. 9, in operation S909, the battery control apparatus according to an embodiment may determine whether the minimum time taken to fully charge the battery is less than the minimum time taken to fully discharge the battery.

Referring to FIG. 9, if the minimum time taken to fully charge the battery is less than the minimum time taken to fully discharge the battery (operation S909—Yes), in operation S910, the minimum time taken to fully charge the battery may be set as the balance time (e.g., T__{allow_bal}).

Referring to FIG. 9, if the minimum time taken to fully charge the battery is greater than the minimum time taken to fully discharge the battery (operation S909—No), in operation S911, the minimum time taken to fully discharge the battery may be set as the balance time (e.g., T__{allow_bal}).

Referring to FIG. 9, in operation S912, the battery control apparatus according to an embodiment may set the balance time (e.g., a balancing allowable time) by using at least one of the minimum time taken to fully charge the battery or the minimum time taken to fully discharge the battery.

Referring to FIG. 9, in operation S913, a deviation resolution range for each balance power may be determined based on setting the balance time.

Referring to FIG. 10, a table 1050 that illustrates a group of batteries determined based on balance power (or balancing power) according to balance time is shown. The deviation resolution range for each balance power may represent the deviation coverage per allowable time in the table 1050.

Referring to the table 1050, the battery control apparatus according to an embodiment may determine the balance power for adjusting the voltage difference between the plurality of battery packs based on setting the balance time. In table 1050, the balance power may include a power preset to the voltage difference between the plurality of battery packs in the second specified mode.

In an embodiment, the battery control apparatus may set the grade of each of the plurality of battery packs by using at least one of balance time, preset power, or any combination thereof.

For example, if the balance power is set to the first power value (e.g., 1.8 kw), because the coverable difference in SOH of the battery packs is determined by a first coverage value (4%), the group of batteries may be divided into 5 groups. For example, if the balance power is set to a second power value (e.g., 2.3 kw), because the coverable difference in SOH of the battery packs is determined by a second coverage value (5%), the group of batteries may be divided into four groups. For example, if the balance power is set to a third power value (e.g., 3.2 kw), because the coverable difference in SOH of the battery packs is determined by a third coverage value (7%), the group of batteries may be divided into three groups. For example, if the balance power is set to a fourth power value (e.g., 4.5 kw), because the coverable difference in SOH of the battery packs is determined by a fourth coverage value (10%), the group of batteries may be divided into two groups. However, embodiments are not limited to the above.

The battery control apparatus according to an embodiment may determine a grade at which a plurality of battery packs is used together, based on the balance power. For example, if a battery (or battery rack) including battery packs included in different grades is used, because safety may not be ensured, the vehicle control apparatus may use the battery packs included in the same grade.

In an embodiment, if a group of batteries (or a group of battery packs) is divided into five groups by setting the balance power to the first power value, because the difference in SOH between battery packs is relatively smaller than if the group is divided into two groups by setting the balance power to the fourth power value, the efficiency of the balancing operation may be improved. However, because the more finely the groups of batteries are divided, the more each battery group is managed separately, if the group of batteries is divided into 5 groups by setting the balance power as the first power value, the management cost may be relatively higher than if the battery group is divided into two groups the balance by setting the balance power as the fourth power value.

Referring to FIG. 11, a table 1150 may include battery groups divided into two groups. Referring to the table 1150, the battery control apparatus may provide the effect of reducing management costs for managing the battery if using a battery group divided into two groups. As described above with reference to FIGS. 6 to 8, the battery control apparatus 100 may improve the efficiency of the balancing operation by simultaneously performing a balancing power derating operation while performing active balancing.

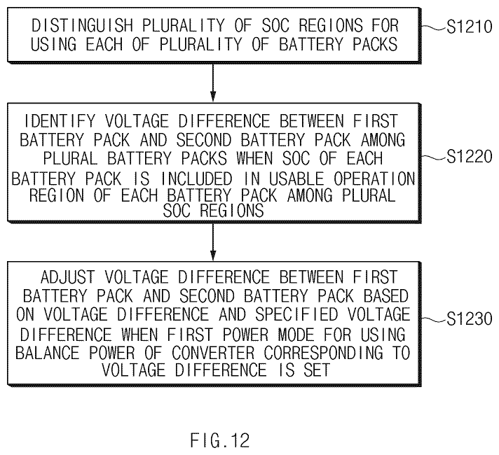

FIG. 12 is a flowchart illustrating an example of an operation of a battery control apparatus according to an embodiment of the present disclosure. Hereinafter, it is assumed that the battery control apparatus 100 of FIG. 1 performs the process of FIG. 12. In addition, it may be understood in the description of FIG. 12 that operations described as being performed by an apparatus are controlled by the processor 110 of the battery control apparatus 100. Each of the operations in FIG. 12 may be performed sequentially but is not necessarily performed sequentially. For example, the order of each operation may be changed, and at least two operations may be performed in parallel. At least one of operations of FIG. 12 may be referenced to at least one of operations of FIGS. 6 to 8.

Referring to FIG. 12, in operation S1210, the battery control apparatus according to an embodiment may distinguish a plurality of SOC regions for using each of a plurality of battery packs (e.g., the first battery pack 141 and the second battery pack 142 in FIG. 1). The plurality of SOC regions may be included in the example 400 of FIG. 4.

Referring to FIG. 12, in operation S1220, if the SOC of each of the plurality of battery packs is included in the usable operation region (e.g., the operation region 410 in FIG. 4) of each of the plurality of battery packs among the plurality of SOC regions, the battery control apparatus according to an embodiment may identify the voltage difference between the first battery pack and the second battery pack among the plurality of battery packs.

The battery apparatus control according to an embodiment may set the operation region by performing at least one of the operations of FIG. 7.

Referring to FIG. 12, in operation S1230, if the first power mode for using the balance power of the converter corresponding to the voltage difference is set, the battery control apparatus according to an embodiment may adjust the voltage difference between the first battery pack and the second battery pack based on the voltage difference and the specified voltage difference. For example, the first power mode may include the normal mode and the max mode included in the table 500 of FIG. 5. Operation S1230 may be related to operations S807 to S811 of FIG. 8.

The battery control according apparatus to an embodiment may determine whether the voltage difference is less than or equal to a specified voltage if the first power mode is set. For example, if the voltage difference is less than or equal to the specified voltage, the battery control apparatus may adjust the voltage difference between the first battery pack and the second battery pack by using the balance power of the converter corresponding to the voltage difference. For example, the battery control apparatus may adjust the voltage difference between the first battery pack and the second battery pack by using the maximum power of the converter if the voltage difference exceeds the specified voltage.

For example, the battery control apparatus may monitor the SOC of each of the plurality of battery packs. The battery control apparatus may temporarily stop adjusting the voltage difference if at least one of the SOC of the first battery pack, the SOC of the second battery pack, or any combination thereof is out of the operation region.

The battery control apparatus according to an embodiment may adjust the voltage difference by using the preset power of the converter if the second power mode differentiated from the first power mode is set.

For example, if the second power mode is set, the battery control apparatus may identify the balance time for adjusting the voltage difference by using Equation 1 and Equation 2 of FIG. 9 based on at least one of the rated energy of the plurality of battery packs, the SOC of each of the plurality of battery packs, the SOH of each of the plurality of battery packs, or any combination thereof. For example, the battery control apparatus may determine a preset power for adjusting the voltage difference based on identifying the balance time. For example, the battery control apparatus may set the grade of each of the plurality of battery packs by using at least one of the balance time, the preset power, or any combination thereof.

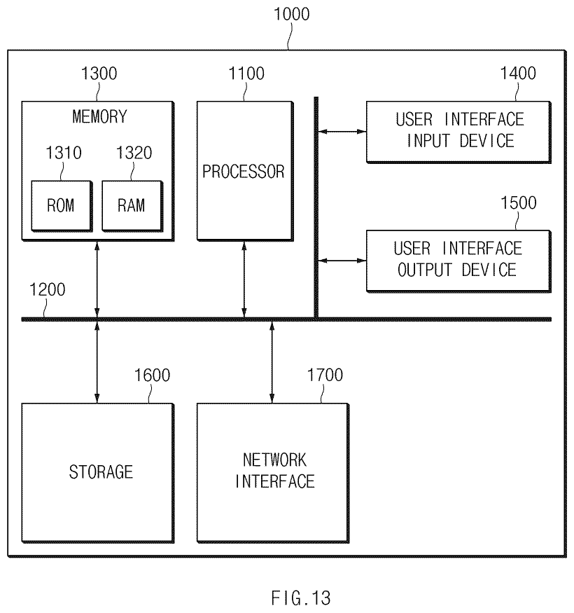

FIG. 13 is a block diagram illustrating a computing system related to a battery control apparatus or a battery control method according to an embodiment of the present disclosure.

Referring to FIG. 5, The computing system 1000 may include at least one processor 1100, a memory 1300, a user interface input device 1400, a user interface output device 1500, storage 1600, and a network interface 1700 connected through a system bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Thus, the operations of the method or the algorithm described in connection with embodiments disclosed herein may be embodied directly in hardware or a software module executed by the processor 1100, or in a combination thereof. The software module may reside on a storage medium (i.e., the memory 1300 and/or the storage 1600) such as a RAM, a flash memory, a ROM, an EPROM, an EEPROM, a register, a hard disk, a removable disk, and a CD-ROM.

The storage medium may be coupled to the processor 1100. The processor 1100 may read information out of the storage medium and may record information in the storage medium. Alternatively, the storage medium may be integrated with the processor 1100. The processor 1100 and the storage medium may reside in an application specific integrated circuit (ASIC). The ASIC may reside within a user terminal. In another case, the processor 1100 and the storage medium may reside in the user terminal as separate components.

The present technology may perform a balancing operation to reduce the voltage difference between battery packs.

The present technology may adjust the power for performing a balancing operation according to the voltage difference between battery packs.

In addition, the present technology may determine the grade of a battery according to the balance time for performing the balancing operation.

In addition, various effects that are directly or indirectly understood through the present disclosure may be provided.

Although embodiments of the present disclosure have been described for illustrative purposes, those having ordinary skill in the art should appreciate that various modifications, additions, and substitutions are possible, without departing from the scope and spirit of the disclosure.

Therefore, the embodiments disclosed in the present disclosure are provided for the sake of descriptions, not limiting the technical concepts of the present disclosure. It should be understood that such embodiments are not intended to limit the scope of the technical concepts of the present disclosure. The protection scope of the present disclosure should be understood by the claims below. All the technical concepts within the equivalent scopes should be interpreted to be within the scope of the right of the present disclosure.

What is claimed is:

1. An apparatus for controlling a battery, the apparatus comprising:
the battery including a plurality of battery packs;
a converter;
a memory; and
a processor,
wherein the processor is configured to
distinguish a plurality of state of charge (SOC) regions for using each of the plurality of battery packs,
identify a voltage difference between a first battery pack among the plurality of battery packs and a second battery pack among the plurality of battery packs when an SOC of each of the plurality of battery packs is included in an operation region in which each of the plurality of battery packs is usable among the plurality of SOC regions, and
adjust the voltage difference between the first battery pack and the second battery pack based on the voltage difference and a specified voltage when a first power mode for using a balance power of the converter corresponding to the voltage difference is set.

2. The apparatus of claim 1, wherein the processor is configured to:
identify whether the voltage difference is less than or equal to the specified voltage when the first power mode is set; and
adjust the voltage difference between the first battery pack and the second battery pack by using the balance power of the converter corresponding to the voltage difference when the voltage difference is less than or equal to the specified voltage.

3. The apparatus of claim 2, wherein the processor is configured to adjust the voltage difference between the first battery pack and the second battery pack by using a maximum power of the converter when the voltage difference exceeds the specified voltage.

4. The apparatus of claim 1, wherein the processor is configured to:
monitor the SOC of each of the plurality of battery packs; and
temporarily stop adjusting the voltage difference when at least one of an SOC of the first battery pack, an SOC of the second battery pack, or any combination thereof is out of the operation region.

5. The apparatus of claim 1, wherein the processor is configured to adjust the balance power according to a state of health (SOH) of each of the plurality of battery packs.

6. The apparatus of claim 1, wherein the processor is configured to distinguish the plurality of SOC regions for using each of the plurality of battery packs according to a state of health (SOH) of each of the plurality of battery packs.

7. The apparatus of claim 1, wherein the plurality of SOC regions includes at least one of:
a hysteresis region for preventing malfunction of the battery;
an operation prohibition region for preventing at least one of overcharge of the battery, over-discharge of the battery, or any combination thereof;
the operation region; or
any combination thereof.

8. The apparatus of claim 1, wherein the processor is configured to adjust the voltage difference by using a preset power of the converter when a second power mode differentiated from the first power mode is set.

9. The apparatus of claim 8, wherein the processor is configured to identify a balance time for adjusting the voltage difference by using at least one of rated energy of the plurality of battery packs, the SOC of each of the plurality of battery packs, a SOH of each of the plurality of battery packs, or any combination thereof when the second power mode is set.

10. The apparatus of claim 9, wherein the processor is configured to determine the preset power for adjusting the voltage difference based on identifying the balance time.

11. The apparatus of claim 9, wherein the processor is configured to set a rating for each of the plurality of battery packs by using at least one of the balance time, the preset power, or any combination thereof.

12. A method of controlling a battery, the method comprising:
distinguishing a plurality of state of charge (SOC) regions for using each of a plurality of battery packs included in the battery;
identifying a voltage difference between a first battery pack among the plurality of battery packs and a second battery pack among the plurality of battery packs when an SOC of each of the plurality of battery packs is included in an operation region in which each of the plurality of battery packs is usable among the plurality of SOC regions; and
adjusting the voltage difference between the first battery pack and the second battery pack based on the voltage difference and a specified voltage when a first power mode for using a balance power of a converter corresponding to the voltage difference is set.

13. The method of claim 12, wherein adjusting the voltage difference includes:
identifying whether the voltage difference is less than or equal to the specified voltage when the first power mode is set; and
adjusting the voltage difference between the first battery pack and the second battery pack by using the balance power of the converter corresponding to the voltage difference when the voltage difference is less than or equal to the specified voltage.

14. The method of claim 13, wherein adjusting the voltage difference includes adjusting the voltage difference between the first battery pack and the second battery pack by using a maximum power of the converter when the voltage difference exceeds the specified voltage.

15. The method of claim 12, wherein adjusting the voltage difference includes:
monitoring the SOC of each of the plurality of battery packs; and
temporarily stopping adjusting the voltage difference when at least one of an SOC of the first battery pack, an SOC of the second battery pack, or any combination thereof is out of the operation region.

16. An apparatus for controlling a battery, the apparatus comprising:
the battery including a plurality of battery packs;
a converter;
a memory; and
a processor,
wherein the processor is configured to
distinguish a plurality of voltage regions for using each of the plurality of battery packs,
identify a voltage difference between a first battery pack among the plurality of battery packs and a second battery pack among the plurality of battery packs when a voltage of each of the plurality of battery packs identified through the converter is included in an operation region in which each of the plurality of battery packs is usable among the plurality of voltage regions, and
adjust the voltage difference between the first battery pack and the second battery pack based on the voltage difference and a specified voltage when a first power mode for using a balance power of the converter corresponding to the voltage difference is set.

17. The apparatus of claim 16, wherein the processor is configured to:
monitor the voltage of each of the plurality of battery packs by using the converter; and
temporarily stop adjusting the voltage difference when at least one of a voltage of the first battery pack, a voltage of the second battery pack, or any combination thereof is out of the operation region.

18. The apparatus of claim 16, wherein the processor is configured to adjust the balance power according to a state of health (SOH) of each of the plurality of battery packs.

19. The apparatus of claim 16, wherein the processor is configured to distinguish the plurality of voltage regions for using each of the plurality of battery packs according to a SOH of each of the plurality of battery packs.

20. The apparatus of claim 16, wherein the plurality of voltage regions includes at least one of:
a hysteresis region for preventing malfunction of the battery;
an operation prohibition region for preventing at least one of overcharge of the battery, over-discharge of the battery, or any combination thereof;
the operation region; or
any combination thereof.
